(19) United States
(12) Patent Application Publication
(10) Pub. No.: US 2010/0283464 A1
(43) Pub. Date: Nov. 11, 2010

(54) MAGNETIC RESONANCE IMAGING USING NAVIGATOR ECHO METHOD WITH NAVIGATOR REGION IN OVERLAP WITH IMAGED REGION

(75) Inventor: Tetsuo Ogino, Tokyo (JP)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/680,937

(22) PCT Filed: Sep. 30, 2008
(86) PCT No.: PCT/IB2008/053964

§ 371 Date: Jun. 22, 2010

(30) Foreign Application Priority Data
Oct. 2, 2007 (JP) 2007-258861

(51) Int. Cl. G01R 33/48

(52) U.S. Cl. 324/309

(57) ABSTRACT

An object of this invention is to provide a Navigator Echo method applicable even when an elongated navigator region and a region of interest to be imaged have a mutually overlapping part. A control section of an MRI apparatus decides, based on a measured signal obtained from a first reception pulse emanated in response to a first transmission pulse which excites a first region to monitor the breathing movement of a subject, whether or not a second region of the subject to be imaged and the first region have a mutually overlapping part, corrects, when the decision result shows that there is an overlapping part, the measured signal obtained from the first reception pulse, and controls a reconstruction unit so as to reconstruct the image of the second region based on the measured signal obtained from a second reception pulse emanated in response to a second transmission pulse which excites the second region and the corrected measured signal.

### TECHNICAL FIELD

The present invention relates to a magnetic resonance imaging apparatus, imaging method and imaging program.

### BACKGROUND ART

A magnetic resonance imaging (MRI) apparatus is an apparatus to use an image of tissue of a human organ containing a large quantity of hydrogen atoms for a medical diagnosis. The MRI apparatus provides an additional gradient magnetic field inside an examination region in which a static magnetic field is generated and transmits consecutive RF pulses generated through an RF transmission coil to a patient who is a subject to be examined located in the examination region of the MRI apparatus. After this, spin resonance pulses emanated from the patient according to the RF pulses are received by an RF reception coil and a received signal obtained from the spin resonance pulses is processed by a reconstruction unit so as to form an image of the subject.

When a human being breathes, organs also move as the diaphragm moves. When imaging an organ which moves with this breathing movement using the MRI apparatus, even when images of the same organ are picked up, the imaging position changes every time and this produces blurs in its reconstructed image. To cope with this problem, a Navigator Echo method is known which detects the movement of the diaphragm, narrows down the imaging timing to a timing that satisfies a predetermined condition or shifts the imaging position (e.g., see Patent Documents 1 to 3).

FIG. 10 is a diagram illustrating a Navigator Echo method which is a prior art. FIG. 10A shows a situation in which the position of the diaphragm 102 is detected using a navigator region 103 which is an elongated excited region to acquire an image of the heart 101. FIG. 10B shows a relationship between a diaphragm position 107 and an RF pulse sequence based on a received signal from the navigator region according to the Navigator Echo method.

As shown in FIG. 10B, the Navigator Echo method executes a navigator sequence 104 to excite the navigator region 103 before an actual measurement sequence 105 for a region of interest to be imaged. This navigator sequence 104 allows a signal from the navigator region to be received thus making it possible to recognize the position of the diaphragm.

Then, only if the recognized diaphragm position falls within a predetermined tolerance range 106, data can be acquired through the actual measurement sequence 105 (that is, data is not acquired at a timing 113 which corresponds to a third navigator sequence in FIG. 10B). This is called a “Gating mode” and by narrowing down the imaging timings to timings that satisfy a predetermined condition, it is possible to reduce position errors included in imaging data.

Also, it is possible to shift the imaging position according to the diaphragm position at timings 111, 112 and 113 in each navigator sequence 104. The diaphragm position is represented by the distance from the origin and FIG. 10B shows distances d1, d2 and d3 at the above described timings in case a lower limit of the tolerance range 106 is assumed to be the origin for convenience of explanation. This is called a “Tracking mode”, which can also reduce position errors included in imaging data.

[Patent Document 1] U.S. Pat. No. 6,076,006

[Patent Document 2] U.S. Pat. No. 7,057,388

[Patent Document 3] U.S. Pat. No. 7,170,289

### DISCLOSURE OF INVENTION

However, the conventional Navigator Echo method is not applicable when the elongated navigator region and a region of interest to be imaged have a mutually overlapping part. This is because when the navigator region and the region of interest have a mutually overlapping part, due to a high frequency pulse for excitation by an actual measurement sequence before a navigator sequence, the signal intensity obtained from the navigator region is attenuated and the spatial distribution of the signal intensity is changed.

The conventional Navigator Echo method analyzes the changed spatial signal intensity, and as a result, may possibly erroneously estimate the position of the diaphragm, and is therefore normally applied when the navigator region and the imaging region have no mutually overlapping part such as when imaging the heart by using the recognized diaphragm position. It is also applied when the excitation angle of high frequency pulses for excitation is small as in the case of a gradient echo method and a signal attenuation has no influence, even if there is an overlapping region, on the result of position estimation in the overlapping region. Erroneous position estimation of the diaphragm may bring about disappointing results; in the Gating mode, imaging is not performed at planned imaging timing and thus can last too long, or imaging is performed at timings at which imaging should not be performed and therefore may bring an image taken at a position which has nothing to do with the region of interest and also in the Tracking mode, the imaging position is shifted based on a wrong diaphragm position resulting in imaging at a position which has nothing to do with the region of interest.

Thus, it is an object of the present invention to provide an MRI apparatus or the like that allows imaging without any such constraints.

According to a first aspect of the present invention, the above described object can be achieved by providing a magnetic resonance imaging apparatus including a magnet that generates a static magnetic field in an examination region into which a subject to be examined laid on a bed is carried, a gradient coil that generates a gradient magnetic field in the examination region, a transmission/reception RF coil that receives reception pulses emanated from the subject in response to transmission pulses, a reconstruction section that reconstructs an image of the subject using a measured signal obtained from the reception pulses, and a control section that controls the gradient coil, the transmission/reception RF coil and the reconstruction unit. The control section decides, based on a measured signal obtained from a first reception pulse emanated in response to a first transmission pulse which excites a first region to monitor the breathing movement of the subject, whether or not a second region of the subject to be imaged and the first region have a mutually overlapping part, corrects, when the decision result shows that there is an overlapping part, the measured signal obtained from the first reception pulse, and controls the reconstruction unit so as to reconstruct the image of the second region, based on the measured signal obtained from a second reception pulse emanated in response to a second transmission pulse which excites the second region and the measured signal obtained from the corrected first reception pulse.

The present invention is implemented based on a perspective that it is possible to detect the presence/absence of aforementioned attenuation in the signal intensity by determining the degree of correlation between the signal obtained from the navigator region and a predetermined rectangular pulse and to remove an imaginary signal caused by the attenuation of the signal intensity by combining a signal correction therewith. In this way, even when the navigator region and the region of interest to be imaged have a mutually overlapping part, for example, the position of the diaphragm can be accurately recognized.

According to a preferred embodiment in the above described aspect of the present invention, the decision is made using a degree of correlation between the measured signal obtained from the first reception pulse and a predetermined reference pulse. Furthermore, the decision may also be made using intensity variation information per distance of the measured signal obtained from the first reception pulse.

According to another preferred embodiment in the above described aspect of the present invention, the reference pulse is rectangular and the width of the reference pulse is substantially equal to a slice thickness of the image for a imaging. Furthermore, a correlation coefficient or covariance may be used as an index indicating the degree of correlation.

According to a further preferred embodiment in the above described aspect of the present invention, corrections are made using linear interpolation, but higher order interpolation such as second-order interpolation may also be used. Furthermore, corrections are made at locations where the degree of correlation exceeds a predetermined threshold, or more specifically locations where the degree of correlation has a maximum value.

Furthermore, according to a second aspect of the present invention, the above described object is attained by providing an imaging method for a magnetic resonance imaging apparatus that reconstructs an image of a subject to be examined using a measured signal obtained from reception pulses emanated from the subject in response to transmission pulses. The method includes a step of deciding, based on a measured signal obtained from a first reception pulse emanated in response to a first transmission pulse which excites a first region to monitor the breathing movement of the subject, whether or not a second region of the subject to be imaged and the first region have a mutually overlapping part, a step of correcting, when the decision result shows that there is an overlapping part, the measured signal obtained from the first reception pulse, and a step of reconstructing the image of the second region, based on the measured signal obtained from a second reception pulse emanated in response to a second transmission pulse which excites the second region and the measured signal obtained from the corrected first reception pulse.

Furthermore, according to a third aspect of the present invention, the above described object is attained by providing a program for causing a control section of a magnetic resonance imaging apparatus that reconstructs an image of a subject to be examined using a measured signal obtained from reception pulses emanated from the subject in response to transmission pulses, to execute following steps; a step of deciding, based on a measured signal obtained from a first reception pulse emanated in response to a first transmission pulse which excites a first region to monitor the breathing movement of the subject, whether or not a second region of the subject to be imaged and the first region have a mutually overlapping part: a step of correcting, when the decision result shows that there is an overlapping part, the measured signal obtained from the first reception pulse: and a step of reconstructing the image of the second region, based on the measured signal obtained from a second reception pulse emanated in response to a second transmission pulse which excites the second region and the measured signal obtained from the corrected first reception pulse.

### BRIEF DESCRIPTION OF DRAWINGS

FIG. 1 is a diagram showing a magnetic resonance imaging (MRI) apparatus according to an embodiment of the present invention; A is an overall view of the MRI apparatus and B is a configuration block diagram of the MRI apparatus.

FIG. 2 is a flow chart illustrating the processing executed by the control section 10 according to the embodiment of the present invention.

FIG. 3 is a flow chart showing a first embodiment of overlapping decision (S20).

FIG. 4 is a diagram illustrating a situation of step S21 when the navigator region and region of interest overlap with each other.

FIG. 5 is a diagram illustrating a situation in step S22.

FIG. 6 is a diagram illustrating a correction according to the first embodiment of overlapping decision.

FIG. 7 is a flow chart showing a second embodiment of overlapping decision (S20).

FIG. 8 is a flow chart showing a third embodiment of overlapping decision (S20).

FIG. 9 is a diagram illustrating a situation of step S25 when the navigator region and region of interest overlap with each other.

FIG. 10 is a diagram illustrating a Navigator Echo method which is a prior art; A shows a situation in which the position of the diaphragm is detected using a navigator region which is an elongated excitation region to perform imaging of the heart and B shows a relationship between a received signal from the navigator region and an RF pulse sequence according to the Navigator Echo method.

### BEST MODE FOR CARRYING OUT THE INVENTION

Hereinafter, embodiments of the present invention will be explained with reference now to the attached drawings. However, the technical scope of the present invention is not limited to such embodiments, but it extends to the invention described in the patent claims and their equivalents.

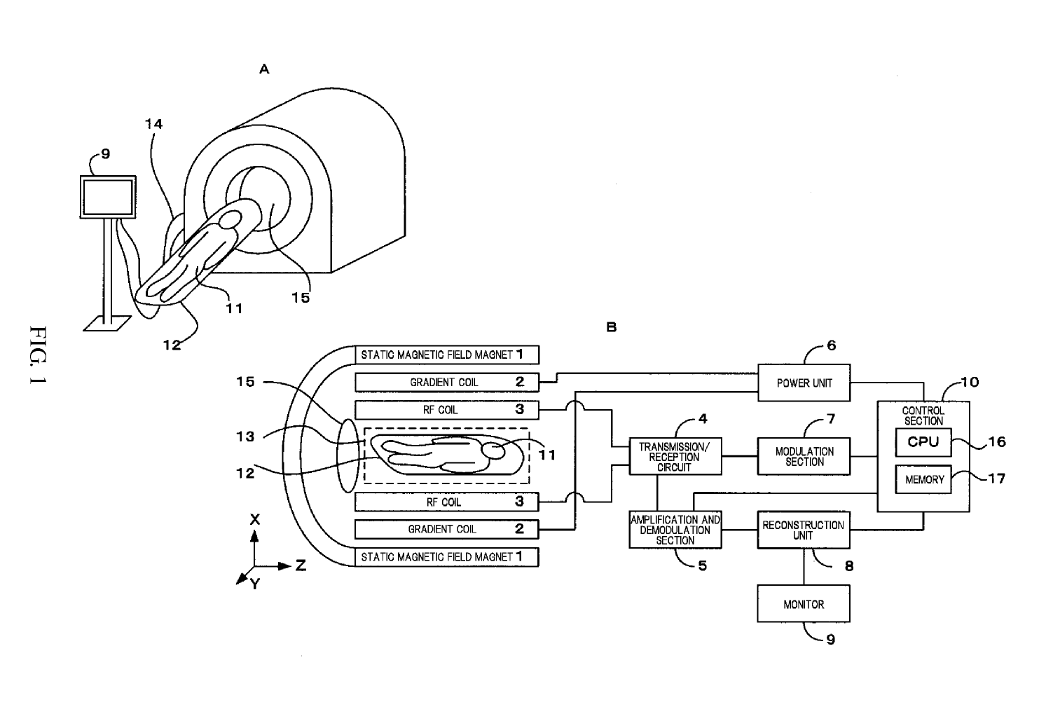

FIG. 1 shows a magnetic resonance imaging (MRI) apparatus according to an embodiment of the present invention. FIG. 1A shows an overall view of the MRI apparatus and FIG. 1B is a configuration block diagram of the MRI apparatus.

FIG. 1A describes a situation in which a patient 11 who is a subject to be examined is placed on a bed 12 and carried into an opening 15 of the MRI apparatus. A monitor 9 is connected to the MRI apparatus using a cable 14.

The MRI apparatus in FIG. 1B includes a static magnetic field magnet 1 that generates a static magnetic field, a gradient coil 2 that generates a gradient magnetic field and an RF coil 3 that transmits transmission pulses to the subject 11 carried into an examination region 13 through the opening 15 and receives reception pulses from the subject. The gradient coil 2 is connected with a power unit 6 for forming a desired gradient magnetic field in an xyz space inside the examination region 13 by changing a current passed through the gradient coil 2.

Thus, pulses are transmitted/received to/from the subject 11 inside the examination region 13 where the static magnetic field and gradient magnetic field are generated. First, a modulation section 7 connected to the RF coil 3 through a transmission/reception circuit 4 gives an electric signal for generating transmission pulses based on a pulse sequence to the RF coil 3 through the transmission/reception circuit 4.

After that, reception pulses which are return pulses caused by magnetic resonance in the subject are received by the same RF coil 3 and a measured signal obtained from the reception pulses is given to an amplification and demodulation section 5 connected to the RF coil 3 through the transmission/reception circuit 4. The amplification and demodulation section 5 acquires phase and amplitude from the measured signal obtained from the reception pulses and gives them to a reconstruction unit 8 connected to the amplification and demodulation section 5. The reconstruction unit 8 processes the given phase and amplitude using a method such as a two-dimensional Fourier transform and outputs to a monitor 9 connected to the reconstruction unit 8 to display an image.

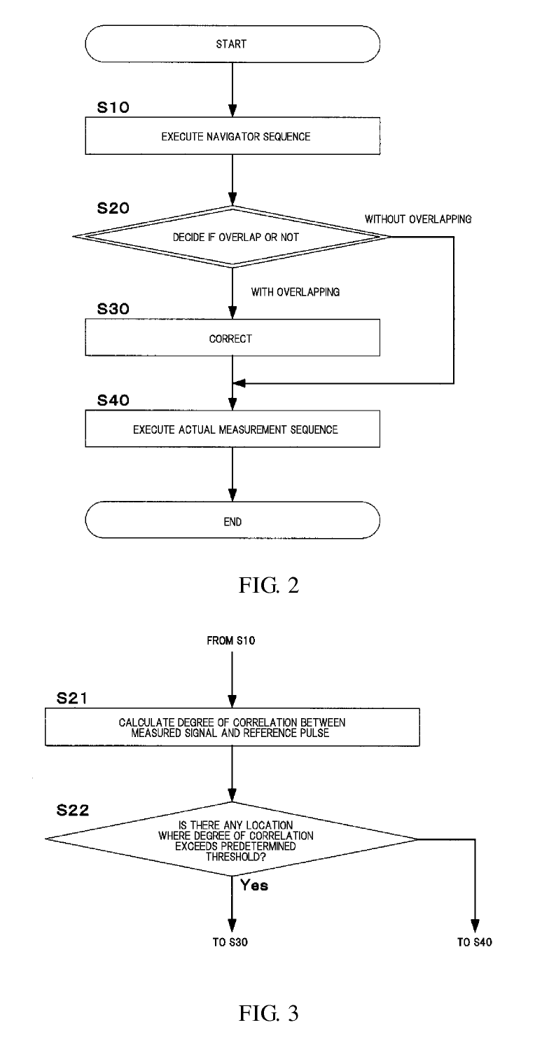

Furthermore, the MRI apparatus also has a control section 10 made up of a CPU or the like for controlling the amplification and demodulation section 5, power unit 6, modulation section 7 and reconstruction unit 8. This control section 10 has a CPU 16 and a memory 17. This memory 17 stores not only information on reference pulses which will be described later but also a program for performing processing which will be described later in FIG. 2 and subsequent figures and a program for controlling the aforementioned amplification and demodulation section 5 or the like.

Though this embodiment describes the RF coil 3 as functioning as a transmission/reception coil, this is not intended to exclude that the transmission coil and reception coil is configured separately.

FIG. 2 is a flow chart illustrating the processing executed by the control section 10 according to the embodiment of the present invention. This figure shows processing carried out between a navigator sequence and actual measurement sequence according to a conventional Navigator Echo method and this processing is intended to decide whether or not a navigator region and a region of interest have a mutually overlapping part and correct, when there is an overlapping part (hereinafter, this case will be referred to “a case of overlapping”), a spatial distribution of signal intensity obtained from the navigator region.

First, the control section 10 performs control for executing a navigator sequence according to the conventional Navigator Echo method (S10). Next, the control section 10 performs control for making an overlapping decision (S20). An overlapping decision can be made using various methods and will be explained in detail using FIG. 3 to FIG. 9.

In the case of overlapping (with overlapping in S20), the control section 10 performs control for correcting the spatial distribution of signal intensity obtained from the navigator region (S30). There are also various such correction methods and will be described in detail later. In the case of no overlapping (without overlapping in S20) or after a correction in step S30, the control section 10 performs control for executing an actual measurement sequence using the conventional Navigator Echo method (S40) and then reconstructs an image based on the acquired data and the processing ends.

FIG. 3 is a flow chart showing a first embodiment of overlapping decision (S20). This overlapping decision method uses a degree of correlation between a measured signal from the navigator region and a reference pulse. First, the control section 10 calculates the degree of correlation between the measured signal from the navigator region input to the amplification and demodulation section 5 and a reference pulse stored in the memory 17 (S21).

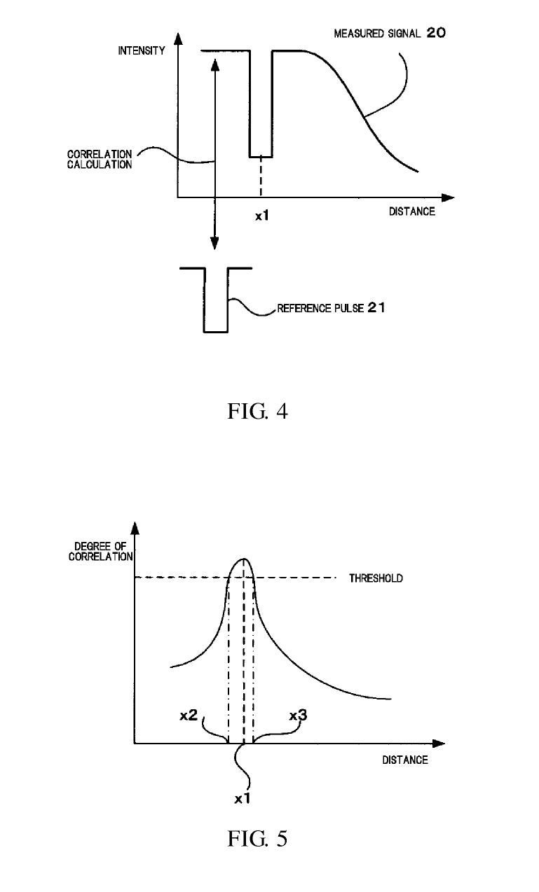

FIG. 4 is a diagram illustrating a situation in step S21 when the navigator region and the region of interest overlap with each other. In FIG. 4, the horizontal axis shows the distance from the origin in the navigator region and the vertical axis shows signal intensity, and a measured signal 20 from the navigator region is expressed as a graph.

Since the navigator region and the region of interest overlap with each other, it is clear from FIG. 4 that there is a rectangular drop at a distance x1 and the signal intensity attenuates. The smooth descending curve on the right shows a decline of the signal due to the diaphragm. Conventionally, the actual diaphragm position cannot be estimated accurately due to such variations in the spatial distribution of signal intensity.

In this embodiment, the control section 10 calculates a degree of correlation between a reference pulse 21 having a rectangular drop and the measured signal 20. A correction coefficient or covariance may be used as an index of the degree of correlation.

For example, a rectangular reference pulse Xi(i=1 . . . n) and a measured signal Yi (i=1 . . . m) can be expressed as functions of the distance i and a correlation coefficient can be calculated for each section [1 . . . n] of reference pulses based on,

$$\frac{{\sum }_{i = 1}^{n} ( {x}_{i} - \overline{x} ) ( {y}_{i} - \overline{y} )}{\sqrt{{\sum }_{i = 1}^{n} {( {x}_{i} - \overline{x} )}^{2}} \sqrt{{\sum }_{i = 1}^{n} {( {y}_{i} - \overline{y} )}^{2}}} ,$$

where

$$\frac{\overline{x}}{y} ,$$

are arithmetic means of Xi and Yi respectively. The arithmetic mean of Yi can be calculated as a mean value in the section [1 . . . n] of reference pulse or a mean value in the section [1 . . . m] of the measured signal may be used.

The rectangular width of the reference pulse 21 is preferably a slice thickness for a imaging.

Returning to FIG. 3, when step S21 is completed, the control section 10 decides whether or not there are locations where the calculated degree of correlation exceeds a predetermined threshold (S22). This is because if there is a rectangular drop similar to the reference pulse exists in the measured signal 20, the degree of correlation increases in the vicinity of the drop. So through the calculation of the degree of correlation in step S21, it is possible to decide the presence/absence of overlapping.

FIG. 5 is a diagram illustrating the situation of step S22. The figure describes the situation in which the degree of correlation increases before and after the distance x1. The parts which will be corrected later may be for example a section [x2, x3] which is a section that exceeds a threshold shown in FIG. 5 or may be a section [x1−Δd, x1+Δd] which corresponds to a predetermined distance Δd around the distance x1 where the degree of correlation becomes a maximum. This threshold can be preset.

Returning to FIG. 3, when the degree of correlation exceeds the predetermined threshold (S22 Yes), the control section 10 performs a correction on the measured signal 20 (S30). This embodiment performs linear interpolation as an example of correction.

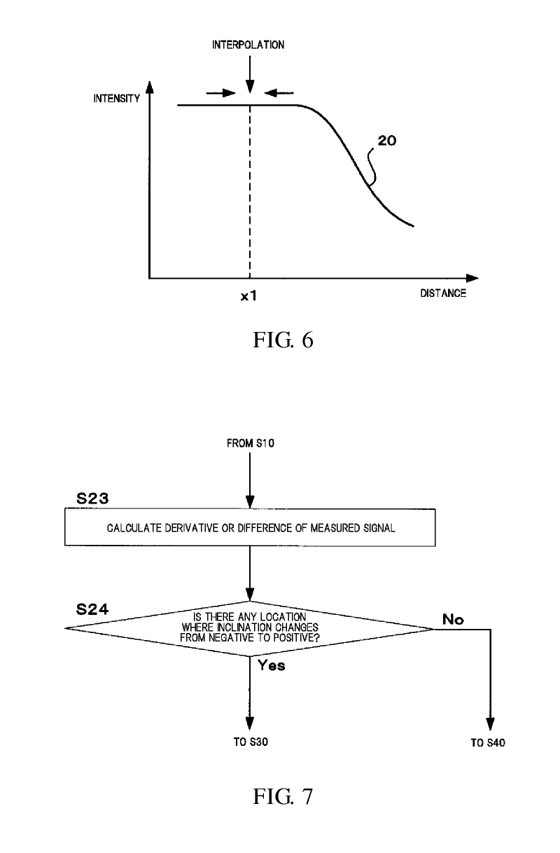

FIG. 6 is a diagram illustrating a correction in the first embodiment of the overlapping decision. In the section where a correction is performed as explained in FIG. 5, linear interpolation may be realized using, for example, values at both ends of the section. In addition to linear interpolation, interpolation can be realized in various modes. For example, interpolation of any order (e.g., second-order curve) may be used if any valley (drastic drop) is avoided in the section where a correction is performed.

Returning to FIG. 3, when the degree of correlation does not exceed the predetermined threshold (S22 No), it is decided that the navigator region and the region of interest do not overlap with each other and an actual measurement sequence is executed without performing any correction (S40). Through the above described processing, the MRI apparatus of this embodiment can estimate the position of the diaphragm with high accuracy even when overlapping occurs. This is because the influence of high frequency pulses by an actual measurement sequence before a navigator sequence is weakened or eliminated in the measured signal after correction.

FIG. 7 is a flow chart showing a second embodiment of overlapping decision (S20). This overlapping decision method uses a variation of inclination in a measured signal from the navigator region.

First, the control section 10 calculates a derivative or difference in the measured signal from the navigator region (S23). A difference between neighboring values can be generally calculated easily, but other calculation can also be adopted. This means that an inclination in the measured signal is observed.

When step S23 is completed, the control section 10 decides whether there are any locations where the calculated derivative or difference changes from negative to positive (S24). This is because when the navigator region and the region of interest overlap with each other, the measured signal shows attenuation and then attempts to return to the original signal level. Thereby the presence/absence of overlapping can be decided based on the inclination of the measured signal.

When there are locations where the calculated derivative or difference changes from negative to positive (S24 Yes), the control section 10 corrects the measured signal 20 (S30). The mode of correction is the same as that described in the first embodiment of overlapping decision.

When there are no locations where the calculated derivative or difference changes from negative to positive (S24 No), it is decided that the navigator region and the region of interest do not overlap with each other and an actual measurement sequence is executed without performing any correction (S40). Effects similar to those in the first embodiment of overlapping decision can also be obtained through the above described processing.

FIG. 8 is a flow chart showing a third embodiment of overlapping decision (S20). This overlapping decision method uses the length of a section where signal intensity is not included within a predetermined range. First, the control section 10 decides whether or not the intensity of a measured signal from the navigator region is within a predetermined range at each location (S25).

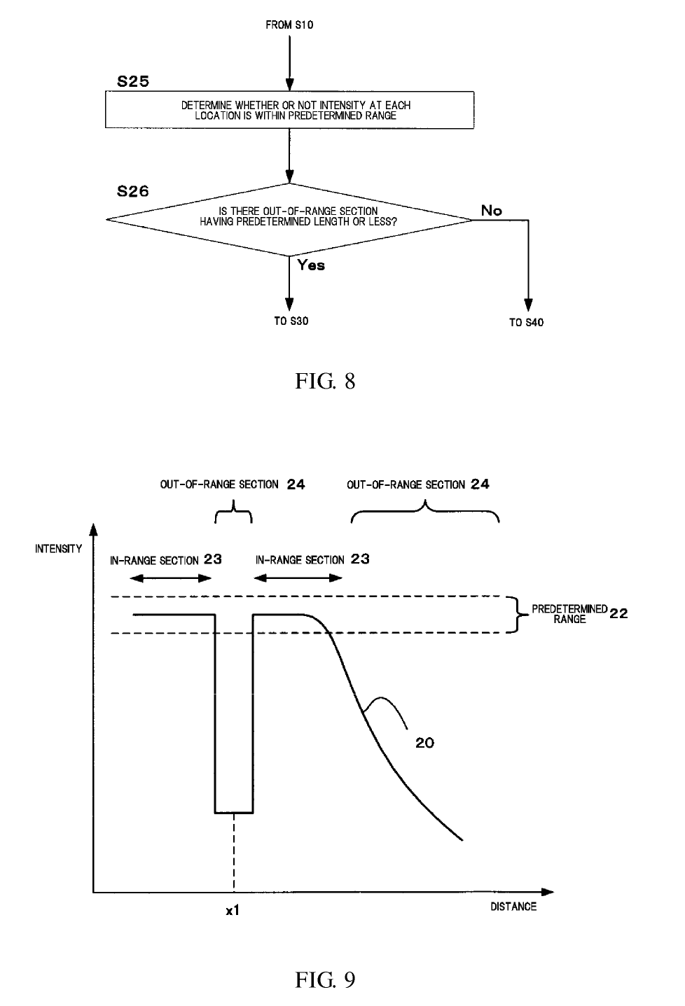

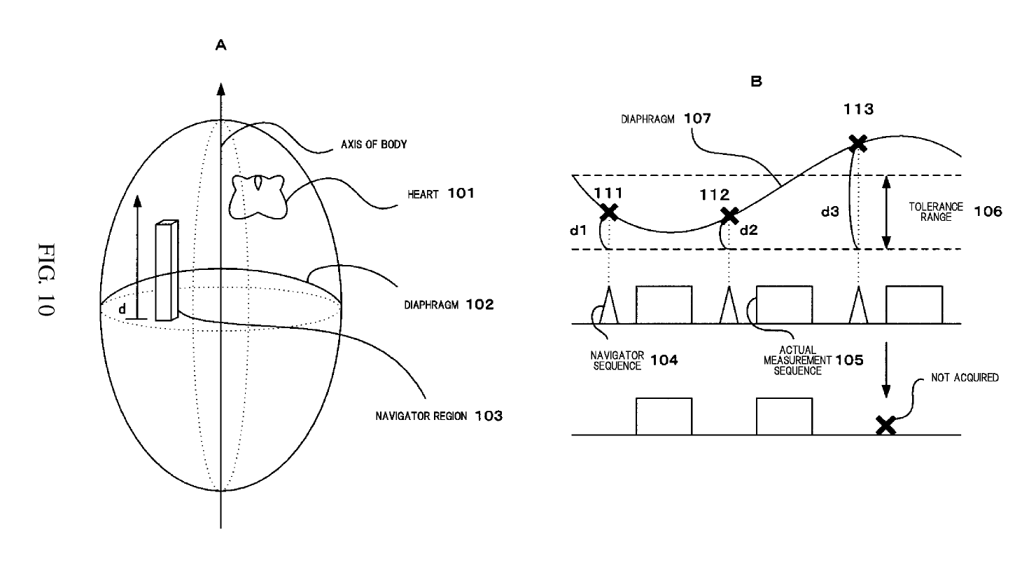

FIG. 9 is a diagram illustrating the situation in step S25 in which the navigator region and the region of interest overlap with each other. The explanation about the measured signal 20 is the same as that in FIG. 4 and will be omitted.

In FIG. 9, a predetermined range 22 is set and each location in the navigator region is classified into an in-range section 23 and an out-of-range section 24 based on whether the intensity at the location is within the predetermined range 22. Of the two sections, the out-of-range section 24 may tend to be relatively short (left side) if the section relates to a drop of a measured signal caused by overlapping, and tend to be relatively long (right side) if the section relates to a drop of a signal caused by the diaphragm.

Returning to FIG. 8, when step S25 is completed, the control section 10 decides whether or not there is any of the above described out-of-range sections having a predetermined length or less (S26). This is because by the above described tendency, it is possible to decide the presence/absence of overlapping.

When there is any of the above described out-of-range sections having a predetermined length or less (S26 Yes), the control section 10 performs a correction on the measured signal 20 (S30). The mode of correction is the same as that described in the first embodiment of overlapping decision.

When there is none of the above described out-of-range sections having a predetermined length or less (S26 No), it is decided that the navigator region and the region of interest do not overlap with each other and an actual measurement sequence is carried out without performing any correction (S40). Effects similar to those in the first embodiment of overlapping decision are also obtained through the above described processing.

As shown above, when the navigator region and a region of interest to be imaged overlap with each other, the MRI apparatus according to the embodiments of the present invention performs a correction on the spatial distribution of signal intensity obtained from the navigator region and thereby allows the position of the diaphragm to be estimated more correctly even when overlapping occurs. This means that there are no more conventional constraints on the imaging region, and it is possible not only to functionally expand the Navigator Echo method but also to fully exploit the Tracking mode and therefore imaging is possible in a shorter imaging time than the Gating mode which has a long imaging time because imaging timings are limited, irrespective of conditions related to imaging positions.

The embodiments of the present invention use a rectangular pulse stored in a memory beforehand as a reference pulse, but pulses other than rectangular pulses can also be used. Furthermore, instead of statically using pulses stored in the memory beforehand, dynamically determined pulses can also be used. When, for example, the shape of a reference pulse is controlled by parameters (e.g., the rectangular width and/or depth are/is parameterized), the control section calculates the degree of correlation while changing the parameter in a preliminary scan before the actual Navigator Echo and can thereby select optimum parameters and dynamically determine the shape of the reference pulse. Furthermore, the control section actually measures a measured signal from the navigator region in a preliminary scan, and can thereby dynamically determine the reference pulse from the actual measurement.

The embodiments of the present invention are applied to cases where the navigator region and the imaging region have an overlapping part and herein the case has explained where a movement of the diaphragm caused by breathing is detected using the navigator region, but the present invention is also applicable to a case where the navigator region is set in the heart to perform imaging of the heart.

The present invention may be implemented as a program to be executed by the CPU 16 in the control section 10 or implemented by hardware or implemented as a method to be executed by an MRI apparatus.

1. A magnetic resonance imaging apparatus comprising:
a magnet that generates a static magnetic field in an examination region into which a subject to be examined laid on a bed is carried;
a gradient coil that generates a gradient magnetic field in said examination region;
a transmission/reception RF coil that receives reception pulses emanated from said subject in response to transmission pulses;
a reconstruction section that reconstructs an image of said subject using a measured signal obtained from said reception pulses; and
a control section that controls said gradient coil, said transmission/reception RF coil and said reconstruction unit,
wherein said control section decides, based on a measured signal obtained from a first reception pulse emanated in response to a first transmission pulse which excites a first region to monitor the breathing movement of said subject, whether or not a second region of said subject to be imaged and said first region have a mutually overlapping part,
corrects, when said decision result shows that there is an overlapping part, the measured signal obtained from said first reception pulse, and
controls said reconstruction unit so as to reconstruct the image of said second region, based on the measured signal obtained from a second reception pulse emanated in response to a second transmission pulse which excites said second region and the measured signal obtained from said corrected first reception pulse.

2. The magnetic resonance imaging apparatus according to claim 1, wherein said decision is made using a degree of correlation between the measured signal obtained from said first reception pulse and a predetermined reference pulse.

3. The magnetic resonance imaging apparatus according to claim 2, wherein said reference pulse is a rectangular pulse.

4. The magnetic resonance imaging apparatus according to claim 3, wherein the rectangular width of said reference pulse is substantially equal to a slice thickness of the image for a imaging.

5. The magnetic resonance imaging apparatus according to claim 2, wherein said degree of correlation is a correlation coefficient or covariance.

6. The magnetic resonance imaging apparatus according to claim 1, wherein said decision is made using intensity variation information per distance of a measured signal obtained from said first reception pulse.

7. The magnetic resonance imaging apparatus according to claim 1, wherein said correction is made using linear interpolation.

8. The magnetic resonance imaging apparatus according to claim 2, wherein said correction is made at a location where the degree of correlation exceeds a predetermined threshold.

9. The magnetic resonance imaging apparatus according to claim 8, wherein said correction is made at a location where said degree of correlation becomes a maximum.

10. An imaging method for a magnetic resonance imaging apparatus that reconstructs an image of a subject to be examined using a measured signal obtained from reception pulses emanated from said subject in response to transmission pulses, comprising:
a step of deciding, based on a measured signal obtained from a first reception pulse emanated in response to a first transmission pulse which excites a first region to monitor the breathing movement of said subject, whether or not a second region of said subject to be imaged and said first region have a mutually overlapping part;
a step of correcting, when said decision result shows that there is an overlapping part, the measured signal obtained from said first reception pulse; and
a step of reconstructing the image of said second region, based on the measured signal obtained from a second reception pulse emanated in response to a second transmission pulse which excites said second region and the measured signal obtained from said corrected first reception pulse.

11. A program for causing a control section of a magnetic resonance imaging apparatus that reconstructs an image of a subject to be examined using a measured signal obtained from reception pulses emanated from said subject in response to transmission pulses, to execute:
a step of deciding, based on a measured signal obtained from a first reception pulse emanated in response to a first transmission pulse which excites a first region to monitor the breathing movement of said subject, whether or not a second region of said subject to be imaged and said first region have a mutually overlapping part;
a step of correcting, when said decision result shows that there is an overlapping part, the measured signal obtained from said first reception pulse; and
a step of reconstructing the image of said second region, based on the measured signal obtained from a second reception pulse emanated in response to a second transmission pulse which excites said second region and the measured signal obtained from said corrected first reception pulse.
